(19) United States
(12) Patent Application Publication
(10) Pub. No.: US 2026/0340811 A1
(43) Pub. Date: Oct. 29, 2026

(54) MEASURING METHOD, LITHOGRAPHY METHOD, ARTICLE MANUFACTURING METHOD, MEASURING APPARATUS, AND LITHOGRAPHY APPARATUS

(71) Applicant: CANON KABUSHIKI KAISHA, Tokyo (JP)

(72) Inventors: HIROMU SUGIYAMA, Tochigi (JP); WATARU YAMAGUCHI, Tochigi (JP)

(21) Appl. No.: 19/653,249

(22) Filed: Apr. 21, 2026

(30) Foreign Application Priority Data
Apr. 23, 2025 (JP) 2025-071746

(51) Int. Cl. G06T 7/00; G06T 7/73

(52) U.S. Cl. CPC G06T 7/001; G06T 7/73; G06T 2207/30121; G06T 2207/30148; G06T 2207/30204

(57) ABSTRACT

The present disclosure provides a measuring method for measuring a position of a mark covered with a light transmission layer in a substrate having the light transmission layer on a surface, comprising: obtaining a state of the light transmission layer on the mark; setting an image capturing condition for capturing the mark via the light transmission layer, based on the obtained state of the light transmission layer; capturing an image of the mark using the set image capturing condition; and determining the position of the mark based on the captured image.

### BACKGROUND

### Field of the Technology

The present disclosure relates to a measuring method, a lithography method, an article manufacturing method, a measuring apparatus, and a lithography apparatus.

### Description of the Related Art

In a lithography apparatus such as an exposure apparatus, alignment precision between a shot region of a substrate and a master and overlay precision between different layers on the substrate are important. Therefore, in the lithography apparatus, a mark (alignment mark) provided on the substrate is captured, and the position of the mark is measured based on an image obtained thereby. Japanese Patent No. 7038737 describes determining alignment parameters for driving a substrate when measuring a mark on the substrate based on a height map of the substrate determined from heights of a plurality of positions on the substrate in order to accurately measure the position of the mark.

In a lithography apparatus, a substrate having a light transmission layer on a surface may be handled. In such a substrate, when capturing a mark covered with the light transmission layer, a captured image of the mark may not be appropriately obtained due to the influence of the light transmission layer. As a result, it may be difficult to accurately measure the position of the mark based on the captured image.

### SUMMARY

The present disclosure provides a technique advantageous for accurately measuring the position of a mark covered with a light transmission layer.

According to one aspect of the present disclosure, there is provided a measuring method for measuring a position of a mark covered with a light transmission layer in a substrate having the light transmission layer on a surface, comprising: obtaining a state of the light transmission layer on the mark; setting an image capturing condition for capturing the mark via the light transmission layer, based on the obtained state of the light transmission layer; capturing an image of the mark using the set image capturing condition; and determining the position of the mark based on the captured image.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic diagram showing a configuration example of a measuring apparatus of a first embodiment.

FIG. 2 is a schematic diagram showing a configuration example of an image capturing unit of the first embodiment.

FIG. 3 is a schematic diagram showing a configuration example of a substrate having a light transmission layer.

FIG. 4 is a diagram showing a result of measuring a surface height of a substrate.

FIG. 5 is a flowchart showing a measuring process of the first embodiment.

FIG. 6 is a diagram showing an example of relationship information indicating a relationship between a state of a light transmission layer and a light intensity ratio.

FIG. 7 is a diagram showing an example of a condition map.

FIG. 8 is a flowchart showing a measuring process of the second embodiment.

FIG. 9 is a schematic diagram showing a configuration example of an exposure apparatus.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

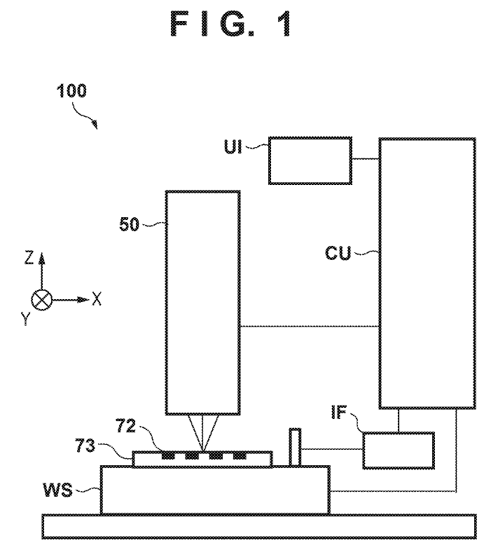

Description will be given of a first embodiment according to the present disclosure. FIG. 1 is a schematic diagram showing a configuration example of a measuring apparatus 100 of the present embodiment. The measuring apparatus 100 is an apparatus that measures the position of a mark 72 (alignment mark) provided on a substrate 73, and may include a substrate stage WS that holds the substrate 73, an image capturing unit 50 that captures the mark 72, a controller CU, and an interface UI. Here, the substrate 73 is, for example, a substrate used for manufacturing a device such as a semiconductor element or a liquid crystal display element, and specifically, is a wafer (for example, a Si substrate), a glass substrate, or another substrate to be processed.

The substrate stage WS holds the substrate 73 via a substrate chuck (not shown) and is driven by a substrate driving mechanism (not shown). The substrate driving mechanism includes a linear motor or the like, and moves the substrate 73 held by the substrate stage WS by driving the substrate stage WS in an X-axis direction, a Y-axis direction, a Z-axis direction, and a rotational direction about each axis as a rotation axis. The position of the substrate stage WS is monitored by, for example, a 6-axis laser interferometer IF, and the substrate stage WS is driven to a target position under control of the controller CU.

The controller CU is configured by a computer (information processing apparatus) including a processor such as a CPU (Central Processing Unit) and a storage unit such as a memory, and comprehensively controls each unit of the measuring apparatus 100 according to a program stored in the storage unit. The controller CU of the present embodiment can perform various processes (arithmetic processes) on an image obtained by capturing the mark 72 of the substrate 73 by the image capturing unit 50 to calculate the position of the mark 72.

The interface UI may include a display device, an input device, and the like. A user can specify, via the interface UI, a shot position to be measured or the mark 72 within a shot region for a plurality of shot regions on the substrate 73.

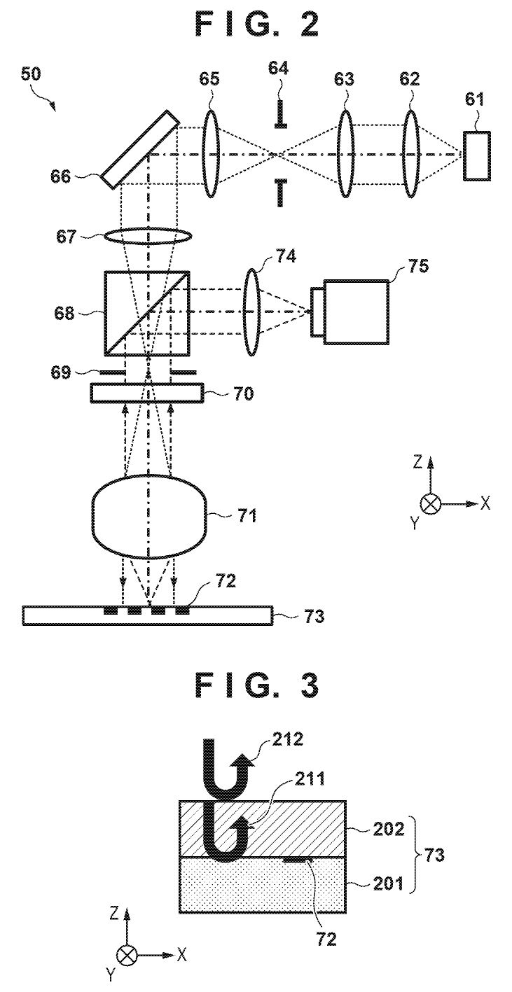

A configuration example of the image capturing unit 50 will be described illustratively with reference to FIG. 2. The image capturing unit 50 may include an illumination optical system that illuminates the substrate 73 using light from a light source 61 and an imaging optical system that forms an image of the mark 72 of the substrate 73 on an image capturing element 75. Note that the image capturing unit 50 may be called an alignment scope.

Light from the light source 61 is guided to an illumination aperture stop 64 via lenses 62 and 63. The light that has passed through the illumination aperture stop 64 is guided to a polarizing beam splitter 68 via a lens 65, a mirror 66, and a lens 67. P-polarized light that has passed through a beam splitting surface of the polarizing beam splitter 68, after passing through an aperture stop 69, is converted into circularly polarized light by a λ/4 plate 70 and illuminates the mark 72 of the substrate 73 via an objective lens 71 using Kohler illumination.

Light resulting from the Kohler illumination is reflected, diffracted, and scattered by the mark 72 passes through the objective lens 71 and the λ/4 plate 70 and is guided to the aperture stop 69. As to the polarization state of the light from the mark 72, the light becomes circularly polarized light in a direction opposite to the circularly polarized light that illuminates the mark 72 by Kohler illumination, and is converted from circularly polarized light to S-polarized light by passing through the λ/4 plate 70. This S-polarized light, after passing through the aperture stop 69, is reflected by the beam splitting surface of the polarizing beam splitter 68 and guided to the image capturing element 75 via a lens 74. The image capturing element 75 may include an image sensor consisting of a CCD, CMOS, or the like.

A light amount adjustment unit (not shown) and/or a wavelength adjustment unit (not shown) may be provided in the illumination optical system. For example, by arranging a plurality of ND filters having mutually different transmittances for light from the light source 61 in a switchable state and controlling switching of the ND filters by the light amount adjustment unit, the intensity of light illuminating the substrate 73 can be adjusted. Also, by arranging a plurality of wavelength filters having mutually different wavelength characteristics of transmitted light for light from the light source 61 in a switchable state and controlling switching of the wavelength filters by the wavelength adjustment unit, the wavelength of light illuminating the substrate 73 can be adjusted. Furthermore, the wavelength adjustment unit may include a wavelength-variable element and a driving mechanism that drives the wavelength-variable element. The driving mechanism includes a linear motor or the like, and can adjust the wavelength of light illuminating the mark 72 of the substrate 73 by driving the wavelength-variable element along a predetermined direction.

Also, the controller CU determines the position of the mark 72 based on position information of the substrate stage WS obtained by the laser interferometer IF and a signal waveform of an image obtained by capturing (detecting) the image of the mark 72 of the substrate 73. The intensity of the signal waveform can be adjusted by changing an image capturing condition of the image capturing unit 50. The image capturing condition may include at least one of the intensity of illumination light for illuminating the substrate 73 (mark 72), a charge accumulation time of the image capturing element 75, and an output gain of the image capturing element 75. The intensity of the illumination light can be adjusted (changed) by, for example, a light amount adjustment unit (ND filter) provided in the illumination optical system of the image capturing unit 50 and/or output control of the light source 61.

Here, FIGS. 1-2 show an example in which one mark 72 on the substrate 73 has a line-and-space structure in which a plurality of lines are arranged along a predetermined direction. However, the mark 72 is not limited to the line-and-space structure and may have another structure. Also, configuration may be taken such that the mark 72 is arranged at each of a plurality of positions on the substrate 73, and the image capturing unit 50 captures each of the plurality of marks 72 on the substrate 73. The image capturing unit 50 may be configured to simultaneously fit two or more marks 72 in an image capturing field of view and simultaneously capture the two or more marks 72. For example, the substrate 73 may be provided with a plurality of shot regions to each of which a pattern of a master is transferred by a lithography apparatus, and at least one mark 72 may be arranged for each shot region.

In a lithography apparatus, a pattern may be formed on the substrate 73 having a light transmission layer on a surface. FIG. 3 shows a configuration example of the substrate 73 having a light transmission layer 202 as a surface layer. The substrate 73 may be configured by stacking, for example, a base layer 201 (light reflection layer) that reflects light of a wavelength used in the image capturing unit 50 (illumination light) and the light transmission layer 202 which is arranged on the base layer 201 and transmits the light.

In such a substrate 73, the mark 72 is provided on the surface of the base layer 201 and is covered by the light transmission layer 202. Therefore, the image capturing unit 50 of the measuring apparatus 100 captures the mark 72 via the light transmission layer 202. However, in this case, illumination light illuminated by the image capturing unit 50 can reflect from both the surface of the base layer 201 and the surface of the light transmission layer 202. Reflected light 211 on the surface of the base layer 201 and reflected light 212 on the surface of the light transmission layer 202 interfere with each other because optical path lengths of the light are different from each other. As a result, the intensity of light incident on the image capturing unit 50 changes according to the thickness (that is, difference in optical path length) of the light transmission layer 202, even if the intensity of the illumination light is constant.

For example, as the substrate 73 having the base layer 201 and the light transmission layer 202, a substrate formed by bonding two types of substrates having different properties from each other, such as a substrate formed by bonding a Si substrate and a SiO₂ substrate, may be used. After bonding the Si substrate and the SiO₂ substrate, the substrate 73 can be formed by performing a polishing process such as MCP (Mechanochemical Polishing) on the surface (the surface on the side opposite to the Si substrate side) of the SiO₂ substrate to thin it. In such a substrate 73, the Si substrate may correspond to the base layer 201, and the SiO₂ substrate may correspond to the light transmission layer 202.

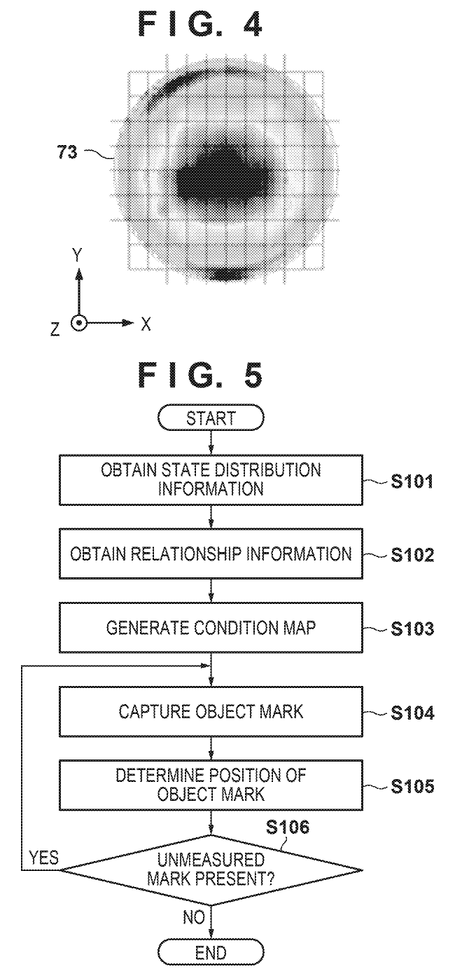

Also, if a SiO₂ substrate as the light transmission layer 202 is bonded onto a Si substrate as the base layer 201, distortion occurs between the two substrates due to thermal deformation or the like at the time of bonding, and a surface height (thickness) of the SiO₂ substrate may change. FIG. 4 shows a result of measuring the surface height of the substrate 73, and the surface height of the substrate 73 is represented in grayscale. The grid shown in FIG. 4 represents a plurality of shot regions on the substrate 73. In the example of FIG. 4, the surface height is different between a central portion and a peripheral portion of the substrate 73, and the surface height changes concentrically. Even if both substrates are flat before bonding, since the SiO₂ substrate is distorted due to the influence of heat at the time of bonding, the distortion of the SiO₂ substrate appears as a change in the surface height (thickness) of the light transmission layer 202.

Therefore, the measuring apparatus 100 (measuring method) of the present embodiment obtains a state of the light transmission layer 202 on the mark 72 in the substrate 73, and sets an image capturing condition for capturing the mark 72 via the light transmission layer 202 by the image capturing unit 50 based on the obtained state of the light transmission layer 202. Accordingly, even in a case where the state of the light transmission layer 202 covering the mark 72 is different for each mark 72, the position of the mark 72 can be accurately measured from an image obtained by the image capturing unit 50.

Here, the state of the light transmission layer 202 includes, for example, at least one of a thickness and a surface height of the light transmission layer 202, and can be detected (measured) by an apparatus provided inside or outside the measuring apparatus 100. The surface height of the light transmission layer 202 can be detected (measured) as an index representing the thickness of the light transmission layer 202 on the premise that the surface height of the base layer 201 is constant.

Also, the image capturing condition can be set so that an evaluation index of an image obtained by the image capturing unit 50 satisfies a standard. The evaluation index may include at least one of a contrast value of an image (that is, contrast value of the mark 72 in an image) and luminance of an image (that is, luminance of the mark 72 in an image). The standard for the evaluation index may be understood as a target range of a contrast value and/or luminance that can keep measurement precision for measuring the position of the mark 72 from an image obtained by the image capturing unit 50 within an allowable range.

FIG. 5 is a flowchart showing a measuring process (measuring method) of the position of the mark 72 in the measuring apparatus 100 of the present embodiment. The flowchart of FIG. 5 can be performed by the controller CU.

In step S101, the controller CU obtains state distribution information indicating a distribution on the substrate (on the mark) regarding the state of the light transmission layer 202. As described above, the state of the light transmission layer 202 may include at least one of the thickness and the surface height of the light transmission layer 202. In the present embodiment, the controller CU obtains, as the state distribution information, height distribution information indicating a distribution of the surface height of the light transmission layer 202 in the substrate 73, as shown in FIG. 4. However, instead of or in addition to the height distribution information, the controller CU may obtain thickness distribution information indicating a distribution of the thickness of the light transmission layer 202 in the substrate 73 as the state distribution information.

In the substrate 73 having the base layer 201 and the light transmission layer 202, it can be assumed that the surface height of the base layer 201 is constant from data such as experiments performed previously. Therefore, the height distribution information can be used as information that can be converted into thickness distribution information indicating the distribution of the thickness of the light transmission layer 202 in the substrate 73. Also, the height distribution information can be obtained, for example, using an external apparatus that can measure the surface height of the substrate 73 without being affected by the thickness of the light transmission layer 202. In this case, in this step S101, the controller CU obtains the height distribution information from the external apparatus. In a case where a height measuring unit that can measure the surface height of the substrate 73 without being affected by the thickness of the light transmission layer 202 is provided in the measuring apparatus 100, the controller CU may obtain (measure) height distribution information (state distribution information) using the height measuring unit.

In step S102, the controller CU obtains relationship information indicating a relationship between the state of the light transmission layer 202 and a light intensity ratio. In the present embodiment, as described above, as the state of the light transmission layer 202, the surface height of the light transmission layer 202 which can be converted into the thickness of the light transmission layer 202 can be used. The light intensity ratio is a ratio of intensity of reflected light from the substrate 73 (that is, intensity of interference light of the reflected light 211 to 212 shown in FIG. 3) to intensity of illumination light for illuminating the substrate 73 by the image capturing unit 50. The light intensity ratio may be understood as the intensity of the reflected light normalized with the intensity of the illumination light as a reference.

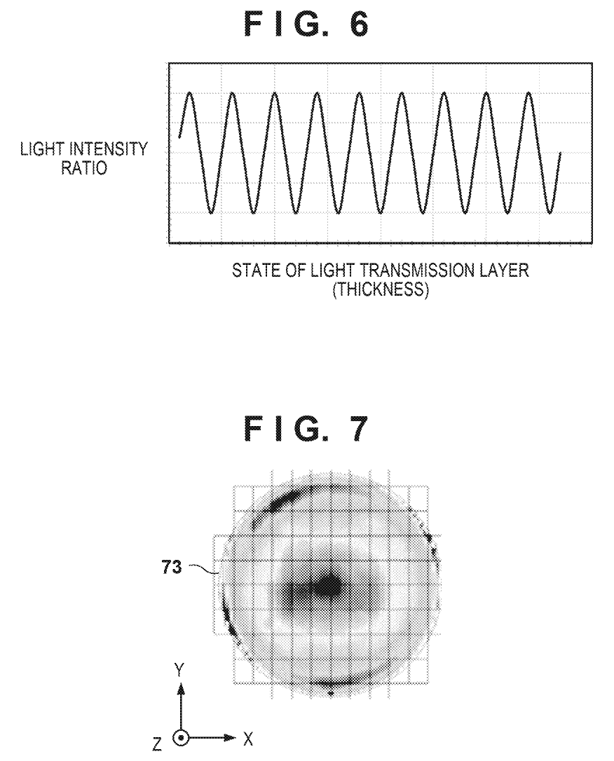

FIG. 6 shows an example of relationship information indicating a relationship between the state (thickness) of the light transmission layer 202 and the light intensity ratio. The relationship information can be obtained (measured) in advance, for example, by an external apparatus using a test substrate for which the state (thickness) of the light transmission layer 202 is known. The relationship between the state of the light transmission layer 202 and the light intensity ratio is represented by a sine curve as shown in FIG. 6. Also, since the relationship between the state of the light transmission layer 202 and the light intensity ratio changes depending on the wavelength of the illumination light, relationship information should be obtained for each of a plurality of wavelengths that can be used for illumination light in the image capturing unit 50.

In step S103, the controller CU generates a map of image capturing conditions on the substrate 73 (hereinafter sometimes referred to as a "condition map") based on the state distribution information and relationship information obtained in steps S101 to S102. The condition map may be understood as a map indicating image capturing conditions of the image capturing unit 50 for each of a plurality of positions where the marks 72 are arranged on the substrate 73. As described above, the image capturing condition of the image capturing unit 50 may include at least one of the intensity of illumination light for illuminating the substrate 73 (mark 72), the charge accumulation time of the image capturing element 75, and the output gain of the image capturing element 75.

For example, for each position (respective coordinates) on the substrate 73, the controller CU determines a light intensity ratio corresponding to the state (surface height, thickness) of the light transmission layer 202 in the state distribution information from the relationship information. Then, based on the determined light intensity ratio, the controller CU sets an image capturing condition at each position so that an evaluation index (contrast value and/or luminance) of an image obtained by the image capturing unit 50 satisfies a standard. In the case of the present embodiment, based on the light intensity ratio determined from the relationship information, the controller CU calculates the intensity of irradiation light for each position so that a decrease in light intensity caused by the light transmission layer 202 is compensated for and the light amount of reflected light (interference light) from the substrate 73 falls within a target range. Accordingly, a condition map can be generated. FIG. 7 shows an example of a condition map, and the intensity of irradiation light as an image capturing condition is represented in grayscale. The grid shown in FIG. 7 represents a plurality of shot regions on the substrate 73.

Here, in the present embodiment, in step S103, a condition map indicating image capturing conditions in the entire area of the substrate 73 is generated, but there is no limitation thereto, and an image capturing condition may be set for each mark 72 provided on the substrate 73. In this case, the controller CU obtains the state of the light transmission layer 202 corresponding to the position on the substrate 73 where the mark is arranged based on the state distribution information. Then, based on the obtained state of the light transmission layer 202 and the relationship information, an image capturing condition for the mark 72 is set so that an evaluation index of an image obtained by the image capturing unit 50 satisfies a standard. That is, step S103 may be understood as a process of setting an image capturing condition for each mark 72. Also, in the condition map, each position on the substrate 73 may be shown by XY coordinates, may be shown using polar coordinates, or may be shown by combining XY coordinates and polar coordinates.

In step S104, the controller CU captures a mark 72 to be measured (hereinafter sometimes referred to as an "object mark 72") among a plurality of marks 72 provided on the substrate 73 by the image capturing unit 50. At this time, the controller CU controls an image capturing condition when capturing the object mark 72 by the image capturing unit 50 based on the condition map generated in step S103. For example, the controller CU sets an image capturing condition corresponding to the position of the object mark 72 based on the condition map, and captures the object mark 72 by the image capturing unit 50 using the set image capturing condition. Note that setting of an image capturing condition based on the condition map may be performed in step S103.

In step S105, the controller CU determines the position of the object mark 72 based on the image obtained by the image capturing unit 50 in step S104. For example, the controller CU can determine the position of the object mark 72 by performing predetermined image processing on the image obtained by the image capturing unit 50. Next, in step S106, the controller CU determines whether there is a mark 72 for which position measurement has not yet been performed (hereinafter sometimes referred to as an "unmeasured mark 72") among the plurality of marks 72 provided on the substrate 73. If there is an unmeasured mark 72, the process proceeds to step S104, and steps S104 to S105 are performed with the unmeasured mark 72 as the object mark 72. On the other hand, if there is no unmeasured mark 72, the flowchart is ended.

As described above, the measuring apparatus 100 of the present embodiment obtains a state of the light transmission layer 202 on the mark 72 in the substrate 73, and sets an image capturing condition for capturing the mark 72 via the light transmission layer 202 by the image capturing unit 50 based on the obtained state of the light transmission layer 202. Accordingly, even in a case where the state of the light transmission layer 202 covering the mark 72 is different for each mark 72, the position of each mark 72 can be accurately measured from an image obtained by the image capturing unit 50. Also, even in a case where an adjustment function for image capturing conditions such as an automatic light adjustment function is provided in the image capturing unit 50, by starting image capturing using image capturing conditions set as in the present embodiment, time required for adjustment of the image capturing conditions can be shortened. That is, productivity can be improved.

Here, in step S101 in the flowchart of FIG. 5, information indicating a distribution of focus measurement values of the substrate 73 may be obtained as state distribution information. The information may be obtained by being measured with an external apparatus. Since a change in thickness of the light transmission layer 202 (SiO₂ substrate) follows a change in focus measurement value, a condition map can be generated even if focus measurement values are used.

### Second Embodiment

Description will be given of a second embodiment according to the present disclosure. In the present embodiment, an example of updating a condition map according to the light amount of reflected light (interference light) detected by the image capturing unit 50 for the mark 72 of at least one position (that is, at least one mark 72) among a plurality of positions on the substrate 73 will be described. Note that the present embodiment basically follows the first embodiment, and can conform to the first embodiment except for matters mentioned below.

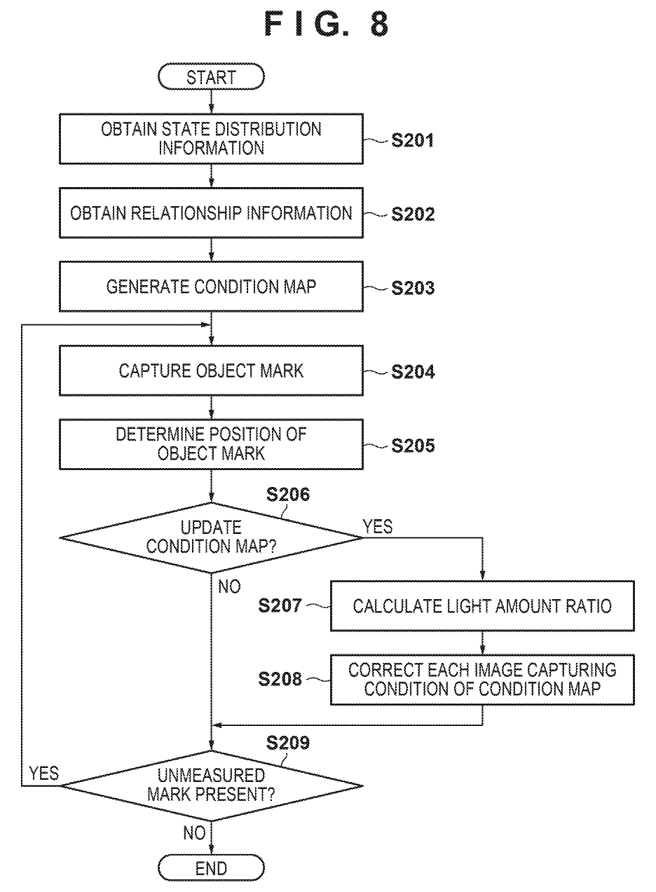

FIG. 8 is a flowchart showing a measuring process (measuring method) of the position of the mark 72 in the measuring apparatus 100 of the present embodiment. The flowchart of FIG. 8 can be performed by the controller CU. Here, steps S201 to S205 in the flowchart of FIG. 8 are similar processes to steps S101 to S105 in the flowchart of FIG. 5, so detailed description thereof is omitted here. However, in the present embodiment, in step S204, the light amount of reflected light (interference light) from the substrate 73 is detected by the image capturing unit 50. The light amount of reflected light may be understood as the intensity of reflected light, or a value obtained by integrating the intensity of reflected light over a charge accumulation time.

In step S206, the controller CU determines whether to update (correct) the condition map based on the light amount of reflected light detected by the image capturing unit 50 in step S204 using the object mark 72. For example, the controller CU calculates a target light amount of reflected light to be obtained for the object mark 72 from the condition map, and compares the light amount of reflected light actually detected by the image capturing unit 50 in step S204 (hereinafter sometimes referred to as an "actual light amount") with the target light amount. Then, if a difference between the actual light amount and target light amount of the reflected light is less than a threshold, it is determined not to update the condition map, and the process proceeds to step S209. On the other hand, if the difference between the actual light amount and target light amount of the reflected light is equal to or greater than the threshold, it is determined to update the condition map, and the process proceeds to step S207.

In step S207, the controller CU calculates a ratio between the actual light amount and target light amount of the reflected light (hereinafter sometimes referred to as a "light amount ratio"). Next, in step S208, the controller CU corrects each image capturing condition of the condition map (that is, image capturing condition at each position on the substrate 73) based on the light amount ratio calculated in step S207. For example, the controller CU updates the condition map by applying the light amount ratio to the image capturing condition (intensity of irradiation light, charge accumulation time, and/or output gain) of the condition map for the entire area of the substrate 73. Accordingly, for a mark 72 measured after the object mark 72 used for determination of whether to update the condition map, measurement can be performed using the updated condition map. Also, for the object mark 72, re-measurement may be performed using the updated condition map. Here, in the present embodiment, an example of updating the condition map using a light amount ratio has been described, but limitation is not made thereto, and the condition map may be updated using a difference between the actual light amount and target light amount of reflected light.

In step S209, the controller CU determines whether there is an unmeasured mark 72 in the substrate 73. If there is an unmeasured mark 72, the process proceeds to step S204. On the other hand, if there is no unmeasured mark 72, the flowchart is ended.

As described above, in the present embodiment, the condition map is updated according to the light amount of reflected light detected by the image capturing unit 50. Accordingly, since image capturing conditions of the image capturing unit 50 can be set more appropriately, the position of each mark 72 can be accurately measured. Also, time required for automatic adjustment of image capturing conditions in the image capturing unit 50 can be further shortened, and productivity can be further improved.

### Embodiment of Lithography Apparatus

The measuring apparatus 100 described above can be incorporated into a lithography apparatus. Such a lithography apparatus includes the measuring apparatus 100 and a formation system that forms a pattern on a substrate. The formation system positions the substrate based on a measurement result of the position of the mark measured by the measuring apparatus 100 (specifically, aligns a master and the substrate) and transfers a pattern of the master onto the positioned substrate.

The lithography apparatus can be, for example, an exposure apparatus or an imprint apparatus. The measuring method described above can be adopted in a lithography method (pattern formation method) for forming a pattern on a substrate. Such a lithography method can include a measuring process of measuring the position of a mark covered with a light transmission layer in a substrate using the measuring method described above, a positioning process of positioning the substrate based on the measurement result, and a formation process of forming a pattern on the positioned substrate.

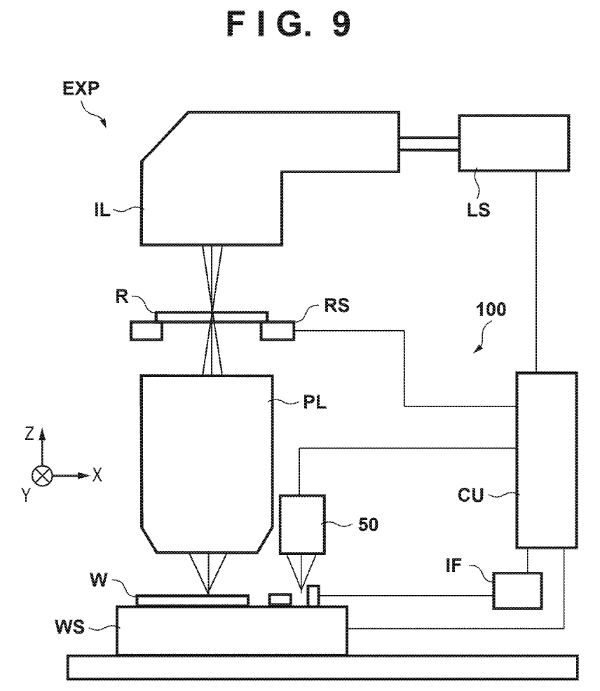

FIG. 9 is a schematic diagram showing a configuration example of an exposure apparatus EXP. The exposure apparatus EXP is used in a lithography process, which is a manufacturing process for a device such as a semiconductor element or a liquid crystal display element, and is a lithography apparatus that forms a pattern on a substrate W. The exposure apparatus EXP transfers a pattern of a master R, such as a mask or a reticle, onto the substrate W by exposing the substrate W via the master R. The exposure apparatus EXP of the present embodiment can be configured to perform scanning exposure of the substrate W by adopting a step-and-scan method, but it is also possible to adopt a step-and-repeat method or another exposure method.

The exposure apparatus EXP has, as shown in FIG. 9, an illumination optical system IL, a master stage RS that holds the master R, a projection optical system PL, a substrate stage WS that holds the substrate W, and a controller CU.

The illumination optical system IL illuminates a surface to be illuminated using light from a light source unit LS. The light source unit LS includes, for example, a laser. Lasers include an ArF excimer laser with a wavelength of approximately 193 nm, a KrF excimer laser with a wavelength of approximately 248 nm, and the like, but the type of light source is not limited to an excimer laser. For example, the light source unit LS may use an F2 laser with a wavelength of approximately 157 nm or EUV (Extreme Ultraviolet) with a wavelength of 20 nm or less as a light source. The illumination optical system IL of the present embodiment shapes light from the light source unit LS into slit light having a predetermined shape optimal for exposure, and illuminates the master R with the slit light. The illumination optical system IL has a function of uniformly illuminating the master R and a function of polarized illumination. The illumination optical system IL includes, for example, a lens, a mirror, an optical integrator, a stop, and the like, and can be configured by arranging a condenser lens, a fly-eye lens, an aperture stop, a condenser lens, a slit, and an imaging optical system in this order.

The master R is made of, for example, quartz. A pattern (circuit pattern) to be transferred onto the substrate W is formed on the master R. Also, the master stage RS holds the master R via a master chuck (not shown) and is driven by a master driving mechanism (not shown). The master driving mechanism includes a linear motor or the like, and moves the master R held by the master stage RS by driving the master stage RS in an X-axis direction, a Y-axis direction, a Z-axis direction, and a rotational direction about each axis as a rotation axis. Note that the position of the master R is measured by a master position measuring unit (not shown) of an oblique light incidence system, and the master R is arranged at a predetermined position by the master stage RS.

The projection optical system PL has a function of forming an image of light from an object plane on an image plane. The projection optical system PL of the present embodiment projects a pattern image of the master R onto the substrate W by irradiating the substrate W with light (diffracted light) that has passed through the pattern of the master R. As the projection optical system PL, an optical system consisting of a plurality of lens elements, an optical system including a plurality of lens elements and at least one concave mirror (catadioptric optical system), an optical system including a plurality of lens elements and at least one diffractive optical element such as a kinoform, or the like is used.

Photoresist is applied onto the substrate W. The substrate W is an object to be processed onto which the pattern of the master R is transferred, and includes a wafer, a liquid crystal substrate, another substrate to be processed, and the like. In the case of the present embodiment, as the substrate W, the substrate 73 having the base layer 201 and the light transmission layer 202 as described above can be used. Also, the substrate stage WS holds the substrate W via a substrate chuck (not shown) and is driven by a substrate driving mechanism (not shown). The substrate driving mechanism includes a linear motor or the like, and moves the substrate W held by the substrate stage WS by driving the substrate stage WS in an X-axis direction, a Y-axis direction, a Z-axis direction, and a rotational direction about each axis as a rotation axis.

The position of the substrate stage WS is monitored by, for example, a 6-axis laser interferometer IF, and the substrate stage WS is driven to a target position under control of the controller CU. Also, the position of the master stage RS is similarly monitored by, for example, a 6-axis laser interferometer, and the master stage RS is driven to a target position under control of the controller CU. By monitoring the positions of the master stage RS and substrate stage WS in this way, the master stage RS and substrate stage WS are relatively driven at a constant speed ratio in scanning exposure of the substrate W.

The controller CU is configured by a computer (information processing apparatus) including a processor such as a CPU and a storage unit such as a memory, and comprehensively controls each unit of the exposure apparatus EXP according to a program stored in the storage unit. The controller CU controls an exposure process of exposing the substrate W via the master R to transfer the pattern of the master R onto the substrate W.

In the exposure apparatus EXP, a pattern image of the master R is projected onto the substrate W via the projection optical system PL by light (diffracted light) that has passed through the master R. The master R and substrate W are arranged at optically conjugate positions via the projection optical system PL. Specifically, the master R can be arranged on the object plane of the projection optical system PL, and the substrate W can be arranged on the image plane of the projection optical system PL. In the exposure apparatus EXP, the pattern of the master R is transferred onto the substrate W by relatively scanning the master R and substrate W at a speed ratio corresponding to a projection magnification of the projection optical system PL.

Also, the exposure apparatus EXP may further include the image capturing unit 50. The image capturing unit 50 has the configuration described in the first embodiment, and captures a mark provided on the substrate W in order to measure the position of the mark. Then, the controller CU measures the position of the mark of the substrate W based on an image obtained by the image capturing unit 50, and controls positioning of the substrate W (specifically, alignment between the master R and substrate W) based on the measurement result. Here, the substrate stage WS, the image capturing unit 50, and the controller CU in the exposure apparatus EXP of the present embodiment can constitute the measuring apparatus 100 that measures the position of a mark of the substrate W (for example, the mark 72 of the substrate 73). Note that in the present embodiment, a common controller CU is provided for the exposure apparatus EXP and measuring apparatus 100, but separate controllers may be provided for the exposure apparatus EXP and measuring apparatus 100.

### Embodiment of Article Manufacturing Method

An article manufacturing method according to an embodiment of the present disclosure is suitable for manufacturing, for example, articles such as microdevices such as semiconductor devices and elements having fine structures. The article manufacturing method of the present embodiment includes a formation process of forming a pattern on a substrate using the lithography apparatus (lithography method) described above, a processing process of processing the substrate on which the pattern has been formed in the formation process, and a manufacturing process of manufacturing an article from the processed substrate. When the lithography apparatus is configured as an exposure apparatus, the formation process can include a process of forming a latent image pattern on a photosensitive agent applied on the substrate by exposing the substrate using the exposure apparatus (exposure method) described above. In this case, the processing process can include a process of developing the substrate on which the latent image pattern has been formed. Furthermore, the article manufacturing method includes other well-known processes (oxidation, film formation, vapor deposition, doping, planarization, etching, resist stripping, dicing, bonding, packaging, etc.). The article manufacturing method of the present embodiment is advantageous in at least one of performance, quality, productivity, and production cost of an article compared to conventional methods.

### Other Embodiments

Embodiments of the present disclosure can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-071746, filed on Apr. 23, 2025, which is hereby incorporated by reference herein in its entirety.

What is claimed is:

1. A measuring method for measuring a position of a mark covered with a light transmission layer in a substrate having the light transmission layer on a surface, comprising:
obtaining a state of the light transmission layer on the mark;
setting an image capturing condition for capturing the mark via the light transmission layer, based on the obtained state of the light transmission layer;
capturing an image of the mark using the set image capturing condition; and
determining the position of the mark based on the captured image.

2. The measuring method according to claim 1, wherein
in the setting, the image capturing condition is set further based on relationship information indicating a relationship between the state of the light transmission layer and a light intensity ratio, and
the light intensity ratio is a ratio of intensity of reflected light from the substrate to intensity of illumination light for illuminating the substrate in the capturing.

3. The measuring method according to claim 2, wherein
the mark is arranged at each of a plurality of positions on the substrate,
in the obtaining, distribution information indicating a distribution on the substrate regarding the state of the light transmission layer is obtained,
in the setting, a map indicating the image capturing condition at each of the plurality of positions is generated based on the distribution information and the relationship information, and
in the capturing, the image capturing condition when capturing the image of the mark at each of the plurality of positions is controlled based on the map.

4. The measuring method according to claim 3, further comprising updating the map according to an amount of reflected light obtained in the capturing the mark at least one position among the plurality of positions.

5. The measuring method according to claim 1, wherein in the obtaining, the state of the light transmission layer corresponding to a position on the substrate where the mark is arranged is obtained based on distribution information indicating a distribution on the substrate regarding the state of the light transmission layer.

6. The measuring method according to claim 1, wherein in the setting, the image capturing condition is set so that an evaluation index of the image to be captured in the capturing satisfies a standard based on the obtained state of the light transmission layer.

7. The measuring method according to claim 6, wherein the evaluation index includes at least one of a contrast value and a luminance of the image.

8. The measuring method according to claim 1, wherein the image capturing condition includes at least one of intensity of illumination light for illuminating the substrate, a charge accumulation time of an image capturing element capturing the mark, and an output gain of the image capturing element.

9. The measuring method according to claim 1, wherein the state of the light transmission layer includes information indicating at least one of a thickness and a surface height of the light transmission layer.

10. A lithography method of forming a pattern on a substrate having a light transmission layer on a surface, comprising:
measuring a position of a mark covered with the light transmission layer in the substrate, using the measuring method according to claim 1;
positioning the substrate based on a measurement result of the measuring; and
forming a pattern on the substrate positioned in the positioning.

11. An article manufacturing method comprising:
forming a pattern on a substrate using the lithography method according to claim 10;
processing the substrate on which the pattern has been formed; and
manufacturing an article from the processed substrate.

12. A measuring apparatus that measures a position of a mark covered with a light transmission layer in a substrate having the light transmission layer on a surface, comprising:
an image capturing unit configured to capture an image of the mark via the light transmission layer; and
a controller configured to determine the position of the mark based on the image captured by the image capturing unit,
wherein the controller is configured to set an image capturing condition for capturing the mark by the image capturing unit based on a state of the light transmission layer on the mark.

13. A lithography apparatus that forms a pattern on a substrate having a light transmission layer on a surface, comprising:
the measuring apparatus according to claim 12; and
a positioning mechanism configured to position the substrate,
wherein positioning of the substrate by the positioning mechanism is controlled based on a measurement result of the measuring apparatus.
